(19) United States
(12) Patent Application Publication
(10) Pub. No.: US 2008/0173345 A1
(43) Pub. Date: Jul. 24, 2008

(54) ELECTRICAL ENERGY GENERATING DEVICE

(76) Inventors: Samuel Cabot COCHRAN, Brooklyn, NY (US); Teresita COCHRAN, Dorchester, MA (US)

Correspondence Address: IP Patent Docketing;KIRKPATRICK & LOCKHART PRESTON GATES ELLIS LLP, 599 Lexington Avenue, 33rd Floor, New York, NY, 10022-6030, US

(21) Appl. No.: 11/624,854

(22) Filed: Jan. 19, 2007

(51) Int. Cl. H01L 31/042

(52) U.S. Cl. 136/248

(57) ABSTRACT

An electrical generating device combines solar cells and piezoelectric generators into a single generating system, configured in such a manner that the solar cells or the solar cell supporting structures act on the piezoelectric generators, resulting in an electrical generating system that can produce electricity from both solar energy and from the force of the wind.

### STATEMENT REGARDING FEDERALLY SPONSORED RESEARCH OR DEVELOPMENT

(Not applicable.)

### FIELD

Electrical generating systems and devices that do not consume natural resources while generating electricity.

### BACKGROUND OF THE INVENTION

The present invention relates generally to a combined electrical generating device that incorporates one energy generating technology, solar cells, and another energy generating technology, piezoelectric generators, into a single generating system. This combination results in an electrical generating system that can produce electricity from both solar energy and from the force of the wind. The system can be produced in modules that allow it to be deployed in arrays of many different sizes, which allows the system to be used in a variety of locations.

Scientists and engineers have devoted substantial resources towards identifying “alternative” sources of energy-sources that do not require the burning of fossil fuels such as oil, coal, or natural gas. Existing forms of alternative energy include solar panels consisting of arrays of photovoltaic cells or foils; wind-or-water driven generators; and biogas recovery and generation systems. Most of these systems are designed to operate on a large scale, and all of them focus on a single method of energy conversion (solar, wind, or hydro, for example). There is a need for an alternative energy generation system that can be employed on a smaller scale, such as in an urban environment, and that can generate electricity from more than one alternative energy source.

These exist in the prior art a number of energy generating devices and ideas that do not meet this criteria.

For example Damian O'Sullivan has created a solar lampion that can be used both outdoors and indoors. The Solar Lampion is composed of an array of 36 ‘standard size’ solar cells (held together by an open spaced frame), each of which is connected to rechargeable battery that feeds a light-emitting diode (LED). The solar cells convert the sun's energy to electricity during the day to charge the battery. At night, the Lampion can be carried indoors (or outside), and the LED is powered by the charged battery. (http://mocoloco.com/archives/002630.php)

There are a number of manufacturers of Photovoltaic cells. One list can be found at http://www.solarbuzz.com/solarindex/CellManufacturers.htm

Ovonics and IOWA are two different manufacturers that produce the product “Thin Film,” a light and flexible photovoltaic panel that is produced in a “roll-to-roll” method allowing the product to be up to 13″ wide and up to 2400 feet long. Thin Film is an amorphous photovoltaic and uses a thin stainless steel foil and a weatherproof plastic “elastomer polymer” coating. It has a lower rate of efficiency compared to crystalline structure solar panels but can absorb a larger spectrum in varying light conditions. It is more durable than crystalline panels and uses no cadmium and very little silicon.

OKSolar and Unisolar make durable solar roof shingles that would replace conventional asphalt shingles. They cost about $16 per square foot, 20 times what an asphalt shingle costs to install, but are an integrated architectural element that can pay for themselves over 25 years rather than end up in a landfill.

The U.S. Department of Energy's Lawrence Berkeley National Laboratory has developed the first ultra-thin solar cells comprised entirely of inorganic nanocrystals and spin-cast from solution. These dual nanocrystal solar cells are as cheap and easy to make as solar cells made from organic polymers and offer the added advantage of being stable in air because they contain no organic materials. This would ideally be used as a rooftop laminate. See http://www.lbl.gov/Science-Articles/Archive/MSD-nanocrystal-solar-cells.html

Nanosolar has developed nanotechnology and high-yield high-throughput process technology for a thin-film solar device technology. Nanosolar has taken an efficient and durable thin-film device technology, called CIGS (Copper Indium Gallium Diselenide) and has developed thin film solar cells.

In another type of photovoltaic cell, DayStar Technology's LightFoil™ consists of high efficiency CIGS solar cells deposited on thin titanium foil, less than the thickness of common household aluminum foil. The flexibility is both physical and in the foil's form factor, which enables molding to curved surfaces and can be cut to shape to conform to complex geometric requirements. See http)://www.daystartech.com/lightfoil.cfm

Unlike many wind-generating inventions, the present invention does not require the use of large parts, such as, for example, the large propellers that many such generators use to generate electricity from wind energy.

For example, the Helical Vertical Access Windmill called the QuietRevolution (QR5), incorporates three ‘S’ shaped blades that are tapered to shed noise. The windmill's vertical axis is easy to integrate with existing masts and buildings, and the helical (twisted) design captures turbulent winds and eliminates vibration. The windmill's blades, spars and torque tube are made of robust carbon fiber, and all moving parts are sealed to minimize maintenance. The windmill incorporates a direct drive in-line generator with auto-shutdown and peak power tracking that is incorporated into the mast. See http://www.quietrevolution.co.uk/qr5.htm

A piezoelectric windmill has been developed as a laboratory exercise. See Piezoelectric Windmill: A Novel Solution to Remote Sensing—By: Shashank PRI YA, Chih-Ta CHEN, Darren FYE and Jeff ZAHND; —Materials Science and Engineering, University of Texas at Arlington, Arlington, Tex. 76019, U.S.A.; —Japanese Journal of Applied Physics, Vol. 44, No. 3, 2005, pp. L 104-L 107, #2005 The Japan Society of Applied Physics; http://mse.uta.edu/Priya/Piezoelectric%20Windmill.pdf. This windmill applies a rotating force to a camshaft that operates on a series of piezoelectric generators to generate electricity, that is then rectified and stored.

There are a number of manufacturers of traditional large-scale, wind-driven turbine generators. These include Enercon, GE, Nordex, Vestas, Frisa, Soytes, Zhejiang Windey, Carbide, and DeWind. A number of small-scale turbine generating manufacturers also exist, including Abundant Renewable Energy, Bergey Windpower Co., Entegrity Wind Systems, Energy Maintenance Service, Lorax Energy, Northern Power Systems, Solar Wind Works, Southwest Windpower Co., Wind Turbine Industries Corp.

A smaller piezoelectric generator is used to power a radio-frequency signal transmitter called the Lightning Switch. See http://www.lightingswitch.com (as of Jan. 12, 2007). The Lightning Switch is designed to replace a traditional wired wall switch, and it communicates by way of the RF signal with one or more receivers tha are plugged in to powered electrical sockets. When an electrical device is plugged into the receiver, the Lightning Switch will cause the receiver to apply power to (or remove power from) the device. The Lightning Switch receives all of its power from the piezoelectric generator.

None of these, however, combine the features of a solar cell generating system with those of a wind-driven generating system. The present invention's novel combination of piezoelectric generators with solar panels permits the device to generate electricity even in the absence of light of sufficient intensity to cause the photovoltaic foil to generate electricity, provided there is sufficient wind available to drive its piezoelectric generators.

The present invention is designed to be modular, so that its size can be tailored to the amount of space available. Deployed in sufficient numbers, the present invention could generate substantial amounts of electricity.

It would therefore be desirable to use piezoelectric generators combined with solar cells in a modular array of combined generators to produce electricity.

### OBJECTS AND SUMMARY OF THE INVENTION

Accordingly, it is an object of the present invention to produce electricity by combining a device to generate electricity by using photovoltaic cells, which can be referred to as solar cells, with a device for generating electricity by use of piezoelectric generators. The resulting electricity-generating device is a hybrid solar and wind generating panel that combines solar cells and piezoelectric generators into an energy conversion device that is modular and lightweight.

Photovoltaic solar cells are semiconductor devices that convert sunlight into direct current (DC) electricity. Piezoelectric devices are composed of materials that change their geometry or dimensions when an electrical charge is applied to them, and conversely, generate an electrical charge when mechanical pressure is applied to them.

It is another object of the present invention to combine the electrical generating capacity of multiple piezo/solar generators of the present invention in a system that integrates the individual generating capabilities of many generators in a single unified unit.

In accordance with an aspect of the present invention, the structure of the piezo solar generating device can comprise three main parts. The first part is a backing, such as aluminum or plastic, cut into a shape that is sized and shaped to accommodate a solar cell. The second part is a solar cell that is attached to the backing. The third part is a piezoelectric generator, which is positioned such that movement of the backing causes the piezoelectric generator to deform.

The solar cell captures sunlight and converts it to electrical energy. There are several types of solar cells, any of which could be made suitable for use as the solar cell of the subject invention. One type of solar cell consists of a large-area, single layer p-n junction diode, typically made using silicon wafers, that generates electrical energy from light sources with the wavelengths of solar light. Another type of solar cell uses an inexpensive substrate such as glass or ceramic, and is commonly known as a thin-film solar cell. A third type of solar cell does not rely on a traditional p-n junction to separate photogenerated charge carriers. These include photoelectrochemical cells, Polymer solar cells, nanocrystal solar cells, DayStar's™ Copper Indium Gallium diSelenide (CIGS) technology solar cells placed on flexible specialty metal foils, and NANOSOLAR CIGS (Copper Indium Gallium Diselenide) cells, manufactured using nano-scale printing methods.

The movement of the backing, in response to the force of the wind, causes the piezoelectric generator to deform which, given an appropriate amount of force, will cause the piezoelectric generator to produce electricity.

Both the electricity generated by the solar foil and the electricity generated by the piezoelectric generator is stored in an electric storage device, such as one or more capacitors or batteries. The stored electricity can be used as direct current or converted to alternating current through a variety of means that are known to those skilled in the art, such as inverters or by driving a motor generator.

In each embodiment of the present invention, a solar cell is mounted to a movable support plate. The supporting plate is designed so that it moves in response to an outside force, such as wind. The force generated by the moving support plate is applied in a variety of novel ways to a piezoelectric generator. In one embodiment of the present invention, the photovoltaic foil is mounted on a support plate that is flexibly attached to a mounting plate by way of a flexible coupling located at a point between the midpoint and the end of the support plate. The support plate moves in response to an applied force. When it moves, the end of the support plate that is closest to the flexible coupling contacts and moves one end of a piezoelectric generator, causing it to generate electricity.

In another embodiment of the present invention, the solar cell is mounted to a support plate that also comprises a piezoelectric generator. One end of the piezoelectric generator system support plate is attached to a mounting plate that holds it in place. Wind forces act directly on the photovoltaic foil assembly and cause the piezoelectric generator to deform, causing it to generate electricity.

In another embodiment of the present invention, the solar cell is mounted to a support plate that is attached to a pivoting mounting bracket in a “see-saw” type of construction. The pivoting mounting bracket is positioned between two piezoelectric generators. When moved in one direction by the force of the wind acting on the solar cell and support plate, the pivoting mounting bracket applies a force to one of the piezoelectric generators, causing it to deform and generate electricity. When moved in the opposite direction by the force of the wind, the pivoting mounting bracket applies a force to the other piezoelectric generator, causing it to generate electricity. The opposing pressure applied by the two opposing piezoelectric generators on each side of the pivoting mounting bracket causes the pivoting mounting bracket to assume a resting point at a predetermined optimal position.

In another embodiment of the present invention, the solar cell is mounted to a support plate that is attached to a mounting bracket by way of a ball and socket or similar such joint that allows the support plate to move from side to side in response to a force such as the wind. One or more cranks are connected to the support plate that drive a cylinder that includes vanes or cams that act on a piezoelectric generator when the cylinder is rotating, causing the piezoelectric generator to deform as the cylinder turns and to thereby generate electricity.

The above and other objects, features and advantages of the invention will become readily apparent from the following detailed descriptions thereof, which are to be read in connection with the accompanying drawings.

The foregoing description of background art may include insights, discoveries, understandings or disclosures, or associations together with disclosures, that were not known in the relevant art prior to the present invention but which were provided by the invention. Some such contributions of the invention may have been specifically pointed out herein, whereas other such contributions of the invention will be apparent from their context. Merely because a document may have been cited here is not an admission that the field of the document, which may be quite different from that of the invention, is analogous to the field or fields of the present invention.

### BRIEF DESCRIPTION OF THE DRAWINGS

FIG. 1 is a side view of one embodiment of the invention

FIG. 2 is a side view of another embodiment of the invention

FIG. 3 is a side view of still another embodiment of the invention

FIG. 4 is a planar view of a fourth embodiment of the invention

FIG. 5 is a view of a kit that embodies the invention

### DETAILED DESCRIPTION

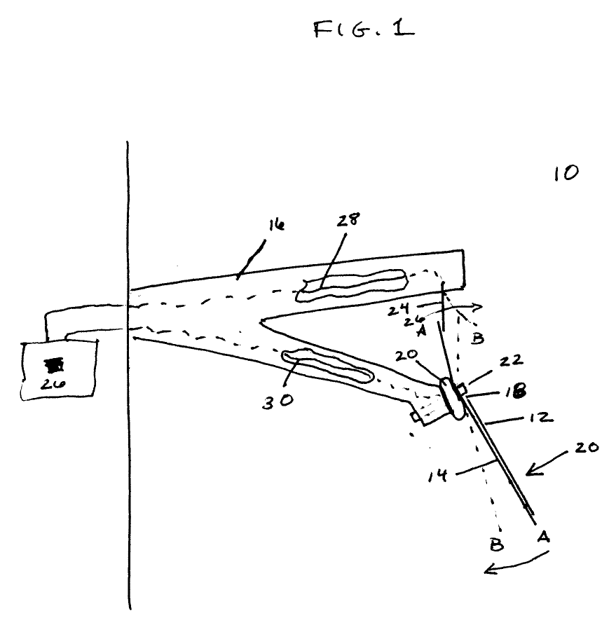

Referring to FIG. 1, an electrical energy generating device 10 is comprised of a solar cell 12 mounted to a movable support plate 14. The movable support plate 14 is affixed to a mounting bracket 16 at a point 18 located between the midpoint of movable support plate 14 and the lower end of movable support plate 14. A flexible material 20 separates movable support plate 14 from mounting bracket 16 so that movable support plate 14 is able to pivot about point 18 in response to an applied force 20 directed towards movable support plate 14. A fastener 22, such as a bolt or a rivet, connects and holds together movable support plate 14, flexible material 20, and mounting bracket 16 so that movable support plate 14 moves relatively freely from starting point A to ending point B in response to applied force 20, and then returns to staring point A when applied force 20 is removed. One end of a piezoelectric generator 24 is attached to mounting bracket 16, such that the other end of piezoelectric generator 24 extends beyond the arc 26 defined by the upper end of movable support plate 14 when it moves from position A to position B in response to force 20. When moving along arc 26, the moving upper end of support plate 14 contacts the end of piezoelectric generator 24, causing piezoelectric generator 24 to deform. The deformation of piezoelectric generator 24 causes it to generate electricity. The generated electricity is transmitted to electricity storage device 26, such as a battery or capacitor, by insulated wire 28.

The solar cell 12 also generates electricity in response to light stimulus of an appropriate intensity. The electricity generated by solar cell 12 is transmitted to electricity storage device 26 by way of insulated wire 30.

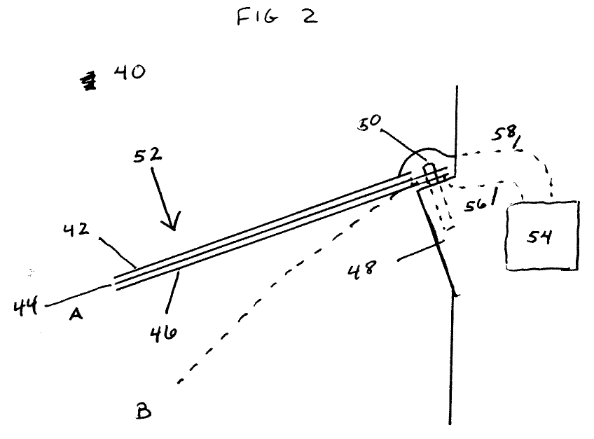

Referring to FIG. 2, an electrical energy generating device 40 is composed of a solar cell 42 that can be mounted to a flexible support plate 44 by an adhesive or a fastener. The flexible support plate 44 is mounted directly on a piezoelectric generator 46 by way of various means known in the art, such as adhesive or fasteners. The piezoelectric generator-photovoltaic foil assembly 42-44-46 is attached to wall mounting plate 48 by way of a fastener 50 such as a bolt or rivet or by similar means. The assembly 42-44-46 moves from point A to point B in response to applied force 52 causing piezoelectric generator 46 to deform, and returns to point A when applied force 52 is removed.

The deformation of piezoelectric generator 46 causes it to generate electricity. The generated electricity is transmitted to electricity storage device 54, such as a battery or capacitor, by insulated wire 56. The solar cell 42 also generates electricity in response to light stimulus of an appropriate intensity. The electricity generated by solar cell 42 is transmitted to electricity storage device 54 by way of insulated wire 58.

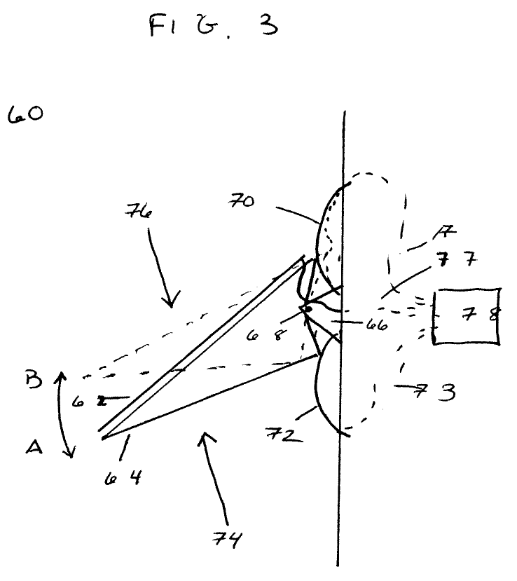

Referring to FIG. 3, an electrical energy generating device 60 is comprised of a solar cell 62 mounted on a rigid support backing 64 by way of various means known in the art, such as adhesive or fasteners. Rigid support backing 64 is configured in a roughly triangular shape, and is attached to mounting plate 66 by way of a movable hinge at mounting point 68. The two ends of rigid support backing 64 that are closest to mounting point 68 each rest against one of the piezoelectric generators 70 or 72. Rigid support backing 64 moves in response to applied force 74 from point A to Point B. In so doing, rigid support backing 64 presses against piezoelectric generator 70, causing it to deform and generate electricity. The electricity so generated is transmitted to electricity storage device 78, such as a battery or capacitor, via insulated wire 71.

Rigid support backing 64 may also move in response to applied force 76 in the opposite direction, causing rigid support backing 64 to press against piezoelectric generator 72, causing it to deform and generate electricity. The electricity so generated is transmitted to electricity storage device 78, such as a battery or capacitor via insulated wire 73. The solar cell 62 also generates electricity in response to light stimulus of an appropriate intensity. The electricity generated by solar cell 62 is transmitted to electricity storage device 78 via insulated wire 77.

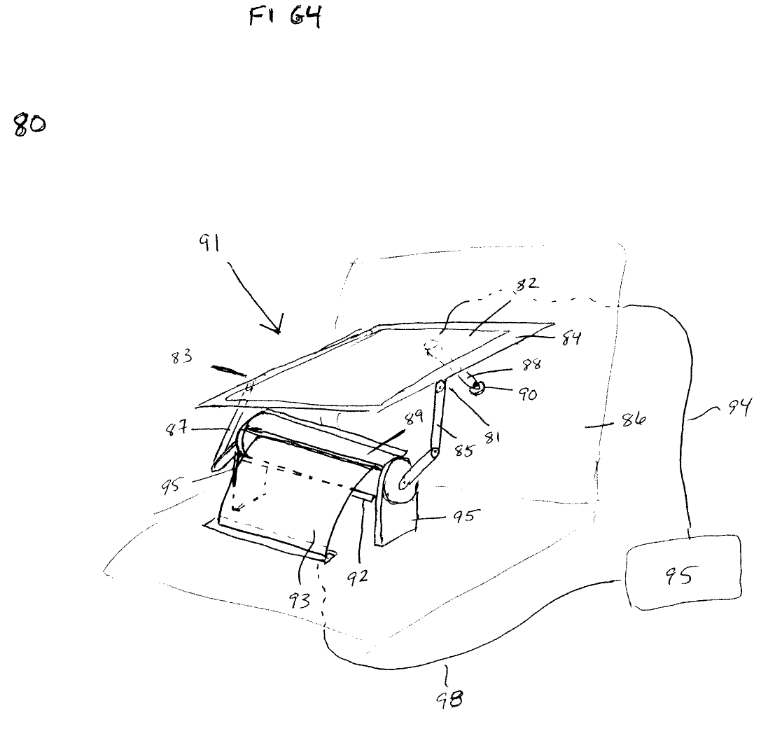

Referring to FIG. 4, an electrical energy generating device 80 is comprised of a solar cell 82 mounted on a rigid support backing 84 by way of various means known in the art, such as adhesive or fasteners. Rigid support backing 84 is attached to mounting plate 86 by way of support arm 88. Support arm 88 is attached to mounting plate 86 by means of flexible joint 90, such as a ball-and-socket joint or other joint known in the art that will both support rigid support backing 84 while allowing it to pivot in a number of different directions. Rigid support backing 84 is also attached to opposed cranks 85 and 87, which in turn are attached to rotating drum 89. Rotating drum 89 is attached to mounting plate 86 by means of drum supports 95. Movement of rigid support backing 84 in response to application of force 91 causes opposed cranks 85 and 87 to turn rotating drum 89. Rotating drum 89 comprises lateral cam vanes 92 that exert a force on one end of piezoelectric generator 93 as rotating drum 89 turns, causing piezoelectric generator 93 to deform and generate electricity. The other end of piezoelectric generator 93 is fixably attached to mounting plate 86. The electricity generated by piezoelectric generator 93 is transmitted to electricity storage device 95, such as a battery or capacitor, via insulated wire 98. Solar cell 82 also generates electricity in response to light stimulus of an appropriate intensity. The electricity generated by solar cell 82 is transmitted to electricity storage device 95 via insulated wire 94.

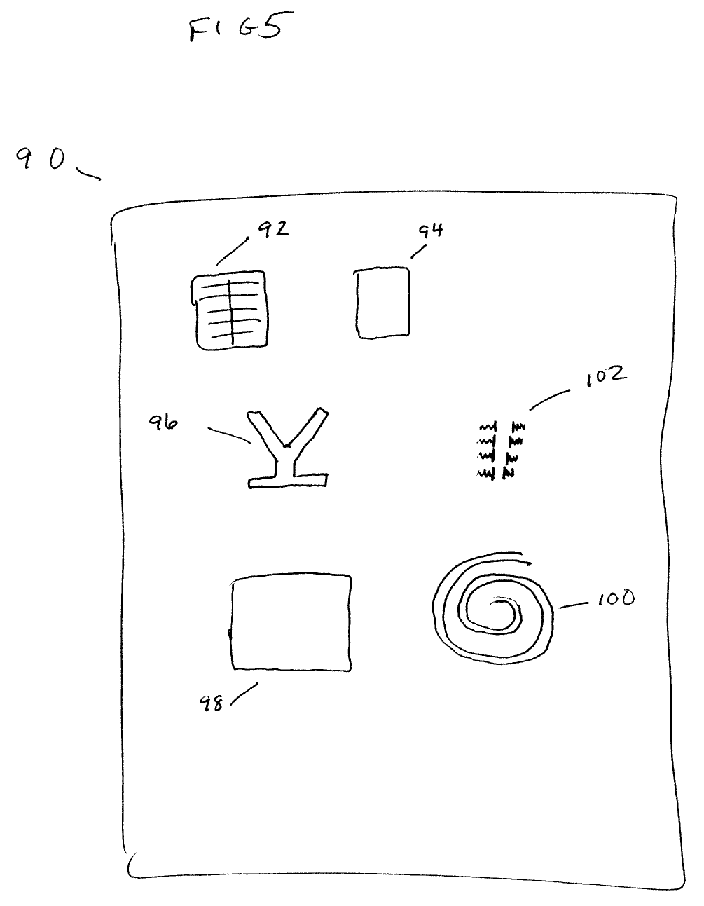

Referring to FIG. 5, an electrical energy generating device kit 90 is comprised of solar cell component 92, a piezoelectric generator 94, a mounting plate 96, an electricity storage device 98, electrical connectors 100, and mounting hardware 102. One or more of these components may be omitted depending on the application. For example, electricity storage device 98 may be omitted if a single electricity storage device will be used to collect and store the electricity generated by more than one device.

In each instance described above, the solar cell can be a LightFoil™ or similar product, supplied by DayStar Technologies, Inc., or others. The piezoelectric generators can be a THUNDER (Thin Layer Unimorph Ferroelectric Driver and Sensor) device, supplied by FACE International, or others.

The present invention can be combined in arrays of varying sizes depending on available space and need for generating capacity. Each such array requires an appropriately-sized energy storage device.

1. An electrical energy generating device comprising a solar cell generator and a piezoelectric generator, each of said generators connected to a mounting means and configured so that movement of said solar cell generator in response to an outside force causes said piezoelectric generator to deform to an extent sufficient to induce said piezoelectric generator to generate electricity.

2. The electrical energy generating device of claim 1 further comprising a support means to which said solar cell generator is attached.

3. The electrical energy generating device of claim 1 further comprising an electricity storage means connected to said solar cell generator and to said piezoelectric generator such that electricity generated by said solar cell generator and by said piezoelectric generator is conducted to and stored by said electricity storage means.

4. The electrical energy generating device of claim 1 where said outside force comprises wind or moving air.

5. The electrical energy generating device of claim 2 where said support means comprises said piezoelectric generator.

6. The electrical energy generating device of claim 2 where said support means is pivotally connected to said mounting means, and one end of said piezoelectric generator is fixably connected to said mounting means, such that said support means contacts the other end of said piezoelectric generator in the course of said movement of said support means in response to said force.

7. The electrical energy generating device of claim 2 where said support means is pivotally connected to said mounting means and both ends of said piezoelectric generator are fixably connected to said mounting means, such that said support means contacts said piezoelectric generator at a point between each end of said piezoelectric generator in the course of said movement of said support means in response to said force.

8. The electrical energy generating device of claim 6 where said support means contacts one piezoelectric generator when said support means moves in one direction in response to said force, and said support means contacts a second piezoelectric generator when said support means moves in a second direction in response to a second force.

9. The electrical energy generating device of claim 2 where the movement of said support means is converted to rotational movement that acts on said piezoelectric generator through one or more cams.

10. An electrical energy generating device comprising a plurality of electrical energy generating devices as set forth in claim 1 that are electrically connected to a single electricity storage and delivery system.

11. An electrical energy generating device kit comprising a solar cell generator and a piezoelectric generator to which said solar cell generator and said piezoelectric generator can be mounted so that movement of said solar cell generator in response to an outside force causes said piezoelectric generator to generate electricity;
hardware to permit said mounting means to be affixed to a structure;
an electricity storage device to store the electricity generated by said solar cell generator and said piezoelectric generator;
electrical conductors to transmit the electricity generated by said solar cell generator and said piezoelectric generator to said electricity storage device.
